(19) United States
(12) Patent Application Publication
(10) Pub. No.: US 2019/0237657 A1
(43) Pub. Date: Aug. 1, 2019

(54) METHOD OF PRODUCING A MULTI-LAYER PIEZOELECTRIC CERAMIC COMPONENT, MULTI-LAYER PIEZOELECTRIC CERAMIC COMPONENT, AND PIEZOELECTRIC DEVICE

(71) Applicant: TAIYO YUDEN CO., LTD., Tokyo (JP)

(72) Inventors: Tomohiro HARADA, Takasaki-shi (JP); Hiroyuki SHIMIZU, Takasaki-shi (JP); Takayuki GOTO, Takasaki-shi (JP); Sumiaki KISHIMOTO, Takasaki-shi (JP); Yukihiro KONISHI, Takasaki-shi (JP)

(21) Appl. No.: 16/258,391

(22) Filed: Jan. 25, 2019

(30) Foreign Application Priority Data
Jan. 30, 2018 (JP) 2018-013964

(51) Int. Cl. H01L 41/273; H01L 41/083; H01L 41/187; H01L 41/047; H01L 41/297; H01L 41/338; H01L 41/312; H01L 41/09

(52) U.S. Cl. CPC H01L 41/273; H01L 41/083; H01L 41/187; H01L 41/09; H01L 41/297; H01L 41/338; H01L 41/312; H01L 41/0471

(57) ABSTRACT

A method of producing a multi-layer piezoelectric ceramic component includes: laminating ceramic green sheets to form a laminate, each of the ceramic green sheets being made of a piezoelectric ceramic material and including an electrically conductive pattern, the electrically conductive pattern including a base metal, being to be an internal electrode, and being formed on an inner side of an outer edge of the ceramic green sheet; sintering the laminate; and cutting the sintered laminate and causing the internal electrodes to be exposed.

### CROSS REFERENCE TO RELATED APPLICATIONS

This application claims the benefit of Japanese Priority Patent Application JP 2018-013964 filed Jan. 30, 2018, the entire contents of which are incorporated herein by reference.

### BACKGROUND

The present disclosure relates to a method of producing a multi-layer piezoelectric ceramic component usable as a piezoelectric actuator, to a multi-layer piezoelectric ceramic component, and to a piezoelectric device.

A bimorph piezoelectric element including a plurality of internal electrodes and a plurality of piezoelectric layers and including a surface electrode on the outermost layer is used for a positioning mechanism or the like (for example, Japanese Patent Application Laid-open No. Hei 9-289342, Japanese Patent Application Laid-open No. 2007-134561, and Japanese Patent Application Laid-open No. Hei 6-252469). The bimorph piezoelectric element includes two-phase piezoelectric ceramics. When a voltage in a positive direction is applied to one of the phases, the piezoelectric ceramics in the phase is expanded by a piezoelectric transversal effect, and a voltage in the inverse direction is applied to the other phase, and the piezoelectric ceramics in the other phase is contracted. This expansion and contraction action bends the piezoelectric element and generates large displacement.

In particular, when the piezoelectric element has a laminated structure, the amount of displacement corresponding to the number of lamination can be obtained. Further, when the thickness is reduced, a voltage to be applied can be reduced.

### SUMMARY

In general, the internal electrodes of the bimorph piezoelectric element are made of a noble metal such as Au, Pt, or Ag, an Ag/Pd alloy, or the like. This is because it is necessary to sinter the piezoelectric ceramics and prevent the internal electrodes from being oxidized in the production process of the bimorph piezoelectric element.

Further, the internal electrodes can also be made of a base metal such as Ni, Cu, or a Ni alloy, which is more inexpensive than the noble metal. In this case, in order to prevent the base metal from being oxidized, it is necessary to adjust the partial pressure of oxygen at the time of sintering on the basis of the Ellingham diagram. Further, since sintering is performed under a low partial pressure of oxygen, an oxygen defect is likely to occur in a crystal lattice, resulting in lack of insulation properties of the piezoelectric ceramics. For that reason, a re-oxidation process becomes necessary, and the increase in number of processes increases production cost.

In such a manner, when an expensive noble metal or a base metal is used for the bimorph piezoelectric element, the re-oxidation process is necessary to perform, and reduction in production cost is expected.

In view of the circumstances as described above, it is desirable to provide a method of producing a multi-layer piezoelectric ceramic component, a multi-layer piezoelectric ceramic component, and a piezoelectric device, which are capable of achieving reduction in production cost.

According to an embodiment of the present disclosure, there is provided a method of producing a multi-layer piezoelectric ceramic component, the method including: laminating ceramic green sheets to form a laminate, each of the ceramic green sheets being made of a piezoelectric ceramic material and including an electrically conductive pattern, the electrically conductive pattern including a base metal, being to be an internal electrode, and being formed on an inner side of an outer edge of the ceramic green sheet; sintering the laminate; and cutting the sintered laminate and causing the internal electrodes to be exposed.

In general, when the internal electrodes include a base metal and are exposed at a surface of the piezoelectric ceramic body in the multi-layer piezoelectric ceramic component, there is a possibility that the internal electrodes are oxidized when the piezoelectric ceramic body is sintered, and the internal electrodes do not function as electrodes. However, if the laminate of the piezoelectric ceramic body and the internal electrodes is sintered and then cut such that the internal electrodes are exposed at the surface of the piezoelectric ceramic body, the internal electrodes can be prevented from being oxidized. Since the internal electrodes are made of a base metal, the material cost is low. Further, since it is unnecessary to control the partial pressure of oxygen at the time of sintering or perform the re-oxidation process for the piezoelectric ceramic body, the production cost can be reduced.

The electrically conductive pattern may include an electrically conductive paste including Ni, Cu, or a Ni alloy.

The laminate may include markers, and the causing the internal electrodes to be exposed may include cutting the laminate at positions of the markers.

The markers may be formed such that an imaginary line connecting the markers passes through the electrically conductive pattern.

The internal electrodes may include first internal electrodes and second internal electrodes, the second internal electrodes being laminated alternately with the first internal electrodes at predetermined distances from the respective first internal electrodes in a thickness direction.

The laminate may be cut to form a piezoelectric ceramic body, the piezoelectric ceramic body having a cuboid shape in which a length is larger than a width and the width is larger than a thickness, and having an upper surface and a lower surface facing each other in the thickness direction, a first end surface and a second end surface facing each other in a length direction, and a pair of side surfaces facing each other in a width direction. The first internal electrodes may be drawn to the first end surface. The second internal electrodes may be drawn to the second end surface.

The first internal electrodes and the second internal electrodes may each have a width equal to a distance between the pair of side surfaces.

The internal electrodes may further include third internal electrodes that are laminated alternately with the second internal electrodes at predetermined distances from the respective second internal electrodes in the thickness direction.

The laminate may be cut to form a piezoelectric ceramic body, the piezoelectric ceramic body having a cuboid shape in which a length is larger than a width and the width is larger than a thickness, and having an upper surface and a lower surface facing each other in the thickness direction, a first end surface and a second end surface facing each other in a length direction, and a pair of side surfaces facing each other in a width direction. The first internal electrodes may be drawn to the first end surface. The second internal electrodes may be drawn to the second end surface. The third internal electrodes may be drawn to the first end surface.

The first internal electrodes, the second internal electrodes, and the third internal electrodes may each have a width equal to a distance between the pair of side surfaces.

According to another embodiment of the present disclosure, there is provided a multi-layer piezoelectric ceramic component including a piezoelectric ceramic body and internal electrodes.

The internal electrodes each include a base metal, are formed in the piezoelectric ceramic body, and are exposed at a surface of the piezoelectric ceramic body.

According to still another embodiment of the present disclosure, there is provided a piezoelectric device including a vibration member and a multi-layer piezoelectric ceramic component mounted to the vibration member.

The multi-layer piezoelectric ceramic component includes a piezoelectric ceramic body and internal electrodes. The internal electrodes each include a base metal, are formed in the piezoelectric ceramic body, and are exposed at a surface of the piezoelectric ceramic body.

As described above, according to the present disclosure, it is possible to provide a method of producing a multi-layer piezoelectric ceramic component, a multi-layer piezoelectric ceramic component, and a piezoelectric device, which are capable of achieving reduction in production cost.

These and other objects, features and advantages of the present disclosure will become more apparent in light of the following detailed description of embodiments thereof, as illustrated in the accompanying drawings.

### BRIEF DESCRIPTION OF DRAWINGS

FIG. 1 is a perspective view of a multi-layer piezoelectric ceramic component according to an embodiment of the present disclosure;

FIG. 2 is a perspective view of the multi-layer piezoelectric ceramic component;

FIG. 3 is a plan view of a first side surface of the multi-layer piezoelectric ceramic component;

FIG. 4 is a plan view of a second side surface of the multi-layer piezoelectric ceramic component;

FIG. 5 is a plan view of a first end surface of the multi-layer piezoelectric ceramic component;

FIG. 6 is a plan view of a second end surface of the multi-layer piezoelectric ceramic component;

FIG. 7 is a plan view of an upper surface of the multi-layer piezoelectric ceramic component;

FIG. 8 is a plan view of a lower surface of the multi-layer piezoelectric ceramic component;

FIG. 9 is a cross-sectional view of a first internal electrode of the multi-layer piezoelectric ceramic component;

FIG. 10 is a cross-sectional view of a second internal electrode of the multi-layer piezoelectric ceramic component;

FIG. 11 is a cross-sectional view of a third internal electrode of the multi-layer piezoelectric ceramic component;

FIGS. 12A and 12B show examples of drive voltage waveforms applied to the multi-layer piezoelectric ceramic component;

FIG. 13 is a perspective view of a multi-layer piezoelectric ceramic component according to a comparative example;

FIG. 14 is a perspective view of the multi-layer piezoelectric ceramic component, which includes an insulating film, according to the embodiment of the present disclosure;

FIGS. 15A to 15E are each a schematic view of a ceramic green sheet to be used for producing the multi-layer piezoelectric ceramic component;

FIG. 16 is a schematic view showing cut positions in a production process of the multi-layer piezoelectric ceramic component;

FIGS. 17A to 17E are each a schematic view showing cut positions in the production process of the multi-layer piezoelectric ceramic component;

FIG. 18 is a cross-sectional view of a multi-layer piezoelectric ceramic component according to another comparative example;

FIG. 19 is a cross-sectional view of the multi-layer piezoelectric ceramic component according to the embodiment of the present disclosure;

FIG. 20 is a schematic view of a piezoelectric device according to the embodiment of the present disclosure; and

FIG. 21 is a perspective view of a multi-layer piezoelectric ceramic component according to a modified example of the present disclosure.

### DETAILED DESCRIPTION OF EMBODIMENTS

A multi-layer piezoelectric ceramic component according to an embodiment of the present disclosure will be described. In each of the following figures, three directions orthogonal to one another will be assumed as an X direction, a Y direction, and a Z direction.

Configuration of Multi-Layer Piezoelectric Ceramic Component

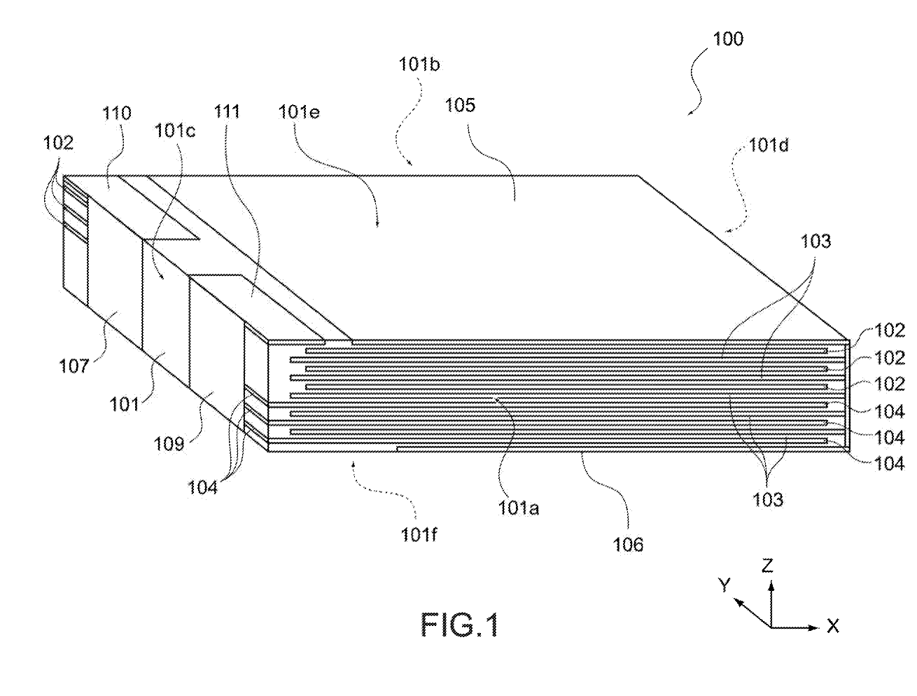

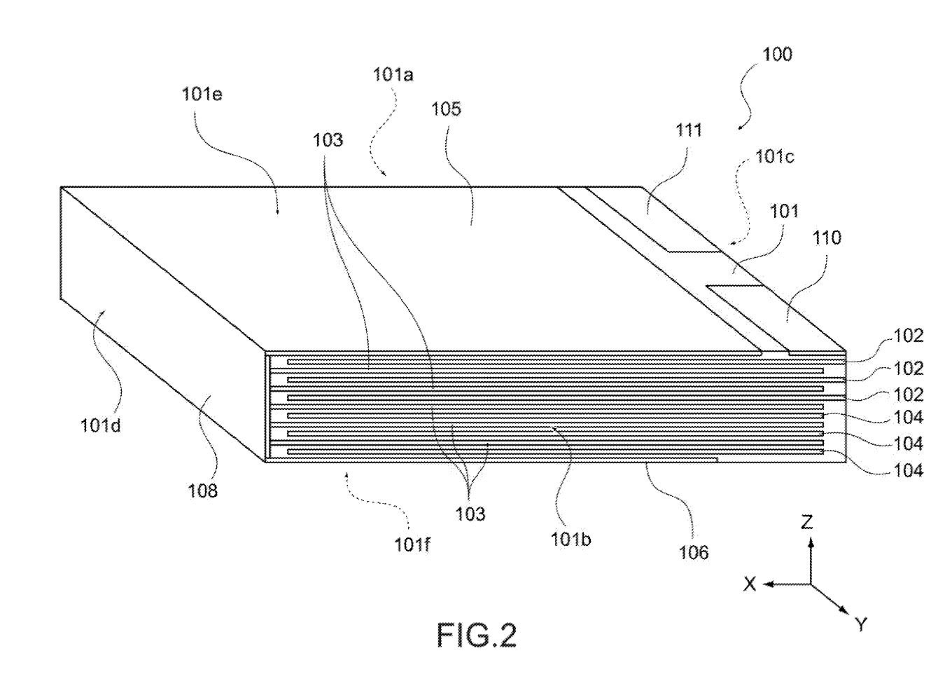

FIGS. 1 and 2 are each a perspective view of a multi-layer piezoelectric ceramic component 100 according to the embodiment. FIG. 2 is a view of the opposite side from FIG. 1.

As shown in FIGS. 1 and 2, the multi-layer piezoelectric ceramic component 100 includes a piezoelectric ceramic body 101, first internal electrodes 102, second internal electrodes 103, third internal electrodes 104, a first surface electrode 105, a second surface electrode 106, a first end surface terminal electrode 107, a second end surface terminal electrode 108, a third end surface terminal electrode 109, a first surface terminal electrode 110, and a second surface terminal electrode 111.

The piezoelectric ceramic body 101 is made of a piezoelectric ceramic material. The piezoelectric ceramic body 101 may be made of, for example, lithium niobate (LiNbO₃), lithium tantalite (LiTaO₃), or lead zirconate titanate (PbZrO₃—PbTiO₃).

As shown in FIGS. 1 and 2, the piezoelectric ceramic body 101 has a cuboid shape. Assuming that the X direction is a length, the Y direction is a width, and the Z direction is a thickness, the piezoelectric ceramic body 101 has such a shape that the length is larger than the width and the width is larger than the thickness (length>width>thickness).

For the surfaces of the piezoelectric ceramic body 101, surfaces facing in the width direction (Y direction) are assumed as a first side surface 101a and a second side surface 101b, and surfaces facing in the length direction (X direction) are assumed as a first end surface 101c and a second end surface 101d. Further, surfaces facing in the thickness direction (Z direction) are assumed as an upper surface 101e and a lower surface 101f.

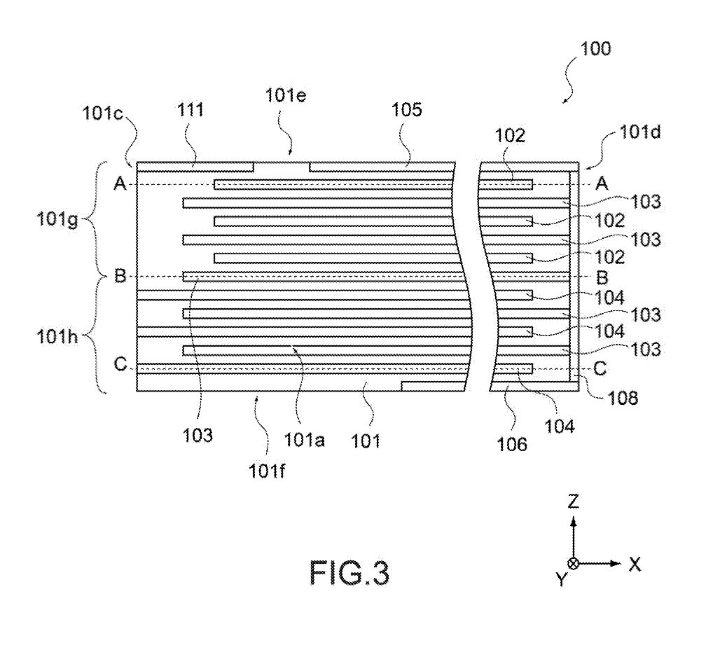

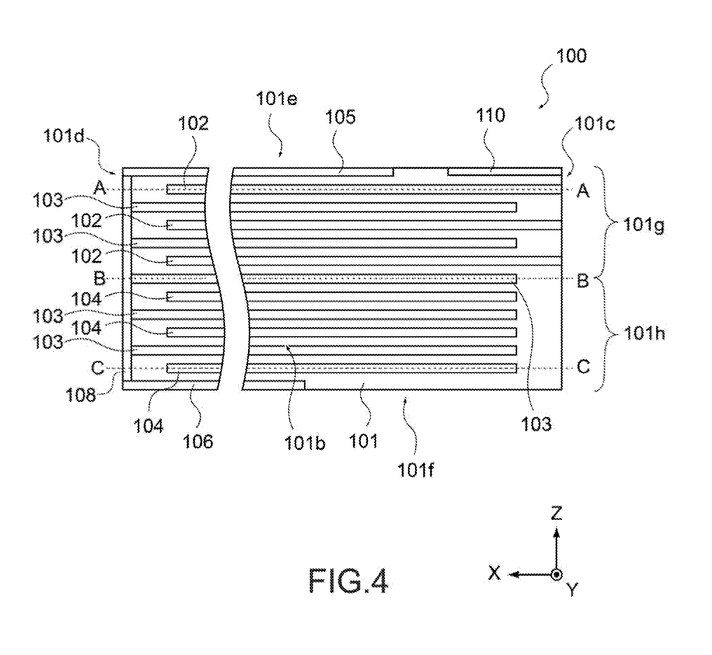

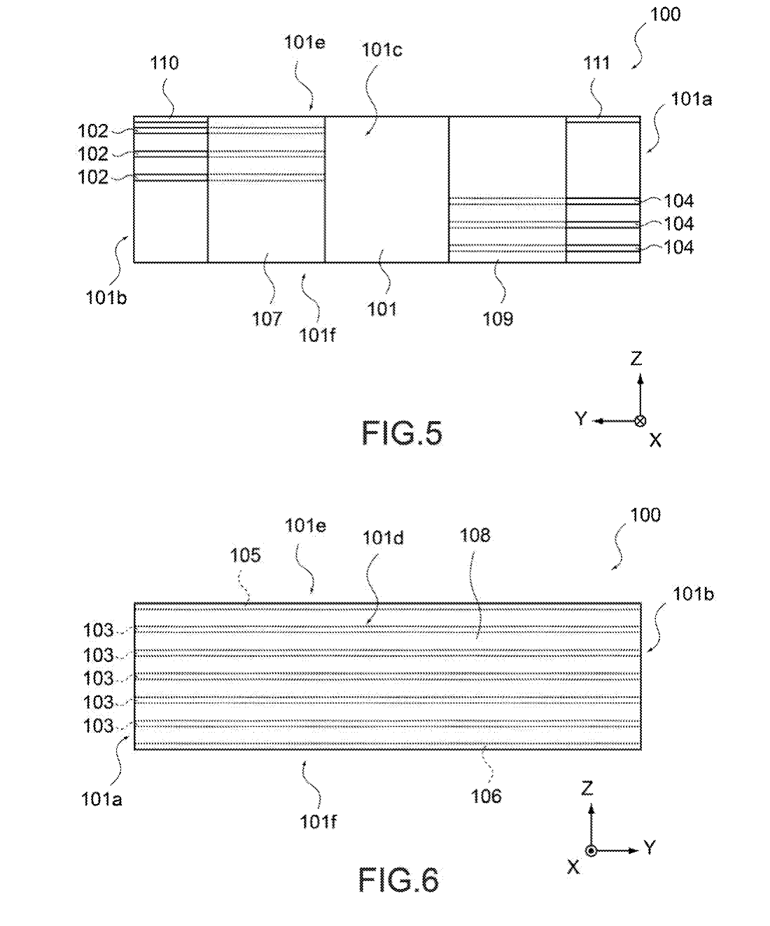

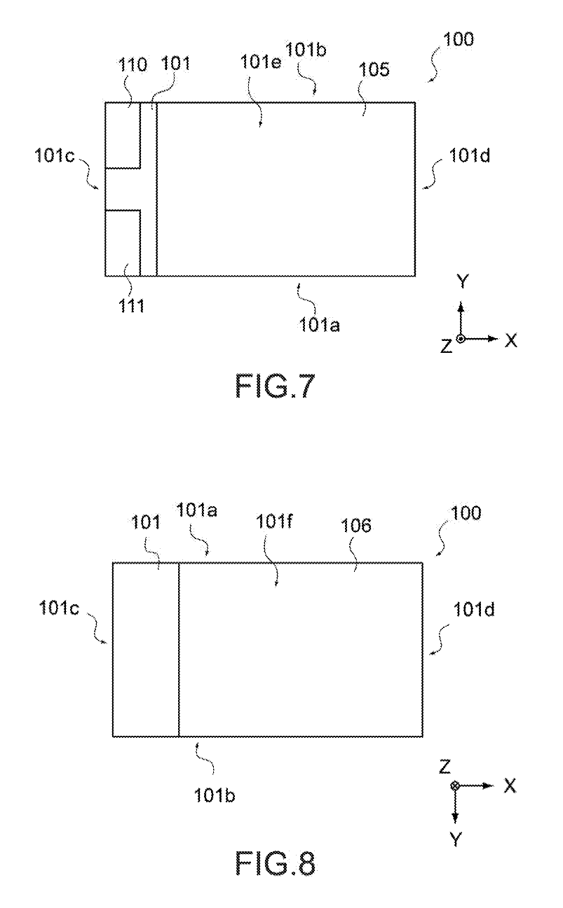

FIG. 3 is a plan view of the first side surface 101a. FIG. 4 is a plan view of the second side surface 101b. FIG. 5 is a plan view of the first end surface 101c. FIG. 6 is a plan view of the second end surface 101d. FIG. 7 is a plan view of the upper surface 101e. FIG. 8 is a plan view of the lower surface 101f.

As shown in FIGS. 3 and 4, the piezoelectric ceramic body 101 includes a first region 101g on the upper surface 101e side and a second region 101h on the lower surface 101f side. The thickness of the first region 101g and the thickness of the second region 101h suitably have a ratio of 1:1.

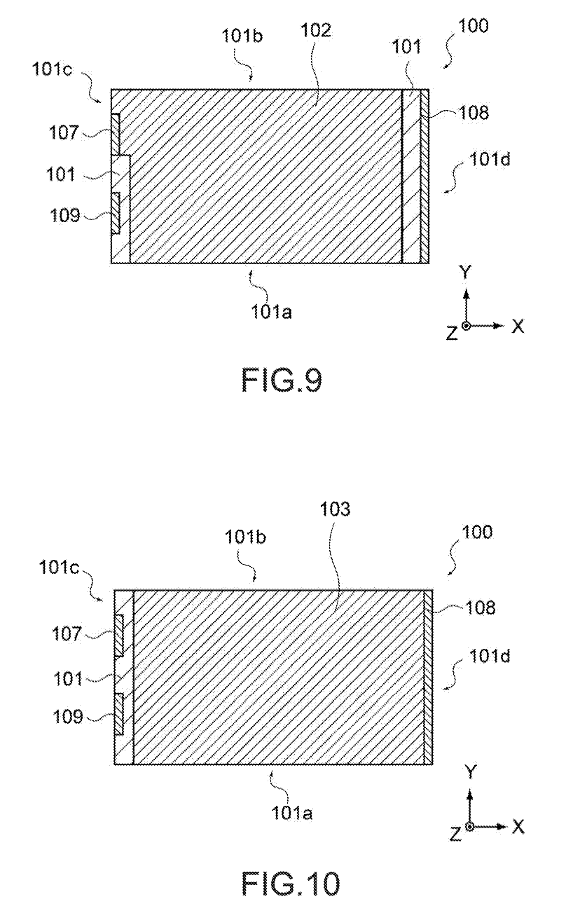

The first internal electrodes 102 are formed in the first region 101g and face the second internal electrodes 103 and the first surface electrode 105 via the piezoelectric ceramic body 101 (see FIGS. 3 and 4). FIG. 9 is a cross-sectional view of the multi-layer piezoelectric ceramic component 100, which shows the first internal electrode 102, and is also a cross-sectional view taken along the line A-A of FIGS. 3 and 4. As shown in FIG. 9, the first internal electrode 102 is drawn to the first end surface 101c, partially exposed at the first end surface 101c, and electrically connected to the first end surface terminal electrode 107.

Further, the first internal electrode 102 has the same width as the width (Y direction) of the piezoelectric ceramic body 101 and is exposed at the first side surface 101a and the second side surface 101b (see FIGS. 3 and 4). The number of first internal electrodes 102 is not particularly limited, and the first internal electrodes 102 may be a single layer or a plurality of layers.

The second internal electrodes 103 are formed in the first region 101g and the second region 101h. The second internal electrodes 103 are laminated alternately with the first internal electrodes 102 in the first region 101g at predetermined distances from the respective first internal electrodes 102 in the thickness direction (Z direction) and face the respective first internal electrodes 102 via the piezoelectric ceramic body 101 (see FIGS. 3 and 4).

Further, the second internal electrodes 103 are laminated alternately with the third internal electrodes 104 in the second region 101h at predetermined distances from the respective third internal electrodes 104 in the thickness direction (Z direction) and face the respective third internal electrodes 104 via the piezoelectric ceramic body 101 (see FIGS. 3 and 4).

FIG. 10 is a cross-sectional view of the multi-layer piezoelectric ceramic component 100, which shows the second internal electrode 103, and is also a cross-sectional view taken along the line B-B of FIGS. 3 and 4. As shown in FIG. 10, the second internal electrode 103 is drawn to the second end surface 101d and electrically connected to the second end surface terminal electrode 108.

Further, the second internal electrode 103 has the same width as the width (Y direction) of the piezoelectric ceramic body 101 and is exposed at the first side surface 101a and the second side surface 101b (see FIGS. 3 and 4). The number of second internal electrodes 103 may be set to correspond to the number of first internal electrodes 102 and the number of third internal electrodes 104.

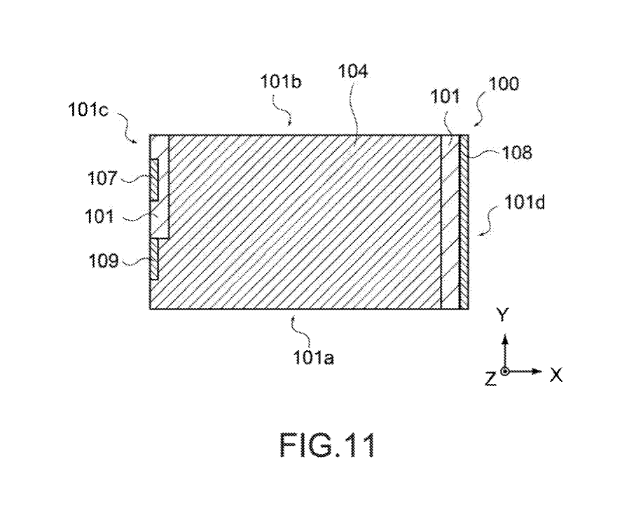

The third internal electrodes 104 are formed in the second region 101h and face the second internal electrodes 103 and the second surface electrode 106 via the piezoelectric ceramic body 101 (see FIGS. 3 and 4). FIG. 11 is a cross-sectional view of the multi-layer piezoelectric ceramic component 100, which shows the third internal electrode 104, and is also a cross-sectional view taken along the line C-C of FIGS. 3 and 4. As shown in FIG. 11, the third internal electrode 104 is drawn to the first end surface 101c, partially exposed at the first end surface 101c, and electrically connected to the third end surface terminal electrode 109.

Further, the third internal electrode 104 has the same width as the width (Y direction) of the piezoelectric ceramic body 101 and is exposed at the first side surface 101a and the second side surface 101b (see FIGS. 3 and 4). The number of third internal electrodes 104 is not particularly limited, and the third internal electrodes 104 may be a single layer or a plurality of layers.

The first surface electrode 105 is formed on the upper surface 101e (see FIG. 1) and is electrically connected to the second end surface terminal electrode 108. Further, the first surface electrode 105 is apart from and electrically insulated from the first surface terminal electrode 110 and the second surface terminal electrode 111 on the upper surface 101e (see FIG. 7).

The second surface electrode 106 is formed on the lower surface 101f and is electrically connected to the second end surface terminal electrode 108 (see FIG. 3).

The first end surface terminal electrode 107 is formed on the first end surface 101c (see FIG. 1) and is electrically connected to the first internal electrodes 102. Further, the first end surface terminal electrode 107 is electrically insulated from the third internal electrodes 104 and the third end surface terminal electrode 109. The first end surface terminal electrode 107 is formed between the upper surface 101e and the lower surface 101f on the first end surface 101c and is electrically connected to the first surface terminal electrode 110.

The second end surface terminal electrode 108 is formed on the second end surface 101d (see FIG. 2) and is electrically connected to the second internal electrodes 103. Further, the second end surface terminal electrode 108 is formed between the upper surface 101e and the lower surface 101f on the second end surface 101d and is electrically connected to the first surface electrode 105 and the second surface electrode 106.

The third end surface terminal electrode 109 is formed on the first end surface 101c (see FIG. 1) and is electrically connected to the third internal electrodes 104. Further, the third end surface terminal electrode 109 is electrically insulated from the first internal electrodes 102 and the first end surface terminal electrode 107. The third end surface terminal electrode 109 is formed between the upper surface 101e and the lower surface 101f on the first end surface 101c and is electrically connected to the second surface terminal electrode 111.

The first surface terminal electrode 110 is formed on the upper surface 101e (see FIG. 1). The first surface terminal electrode 110 is electrically connected to the first end surface terminal electrode 107 and is electrically insulated from the second surface terminal electrode 111 and the first surface electrode 105.

The second surface terminal electrode 111 is formed on the upper surface 101e (see FIG. 1). The second surface terminal electrode 111 is electrically connected to the third end surface terminal electrode 109 and is electrically insulated from the first surface terminal electrode 110 and the first surface electrode 105.

The first internal electrodes 102, the second internal electrodes 103, and the third internal electrodes 104 may each include a base metal. In this embodiment, the base metal means metal species other than noble metals (Au, Ag, Pt, Pd, Rh, Ir, Ru, and Os) and alloys thereof. The first internal electrodes 102, the second internal electrodes 103, and the third internal electrodes 104 are each suitably made of Ni, Cu, or a Ni alloy.

In the multi-layer piezoelectric ceramic component 100, as will be described later, the first internal electrodes 102, the second internal electrodes 103, and the third internal electrodes 104 are embedded in the piezoelectric ceramic body in the production process, and sintering is performed with those internal electrodes not being exposed at a surface of the piezoelectric ceramic body. Accordingly, the first internal electrodes 102, the second internal electrodes 103, and the third internal electrodes 104 may be each made of a base metal, which is easily oxidizable.

Further, at least one of the first internal electrode 102, the second internal electrode 103, or the third internal electrode 104 only needs to include a base metal, and the other internal electrodes may not include a base metal.

The first surface electrode 105, the second surface electrode 106, the first end surface terminal electrode 107, the second end surface terminal electrode 108, the third end surface terminal electrode 109, the first surface terminal electrode 110, and the second surface terminal electrode 111 may include a base metal or may not include a base metal.

The multi-layer piezoelectric ceramic component 100 has the configuration as described above. As described above, the first internal electrodes 102, the second internal electrodes 103, and the third internal electrodes 104 are formed in the piezoelectric ceramic body 101, the first internal electrodes 102 and the second internal electrodes 103 face each other via the piezoelectric ceramic body 101, and the third internal electrodes 104 and the second internal electrodes 103 face each other via the piezoelectric ceramic body 101. The first internal electrodes 102, the second internal electrodes 103, and the third internal electrodes 104 are insulated from one another.

The size of the multi-layer piezoelectric ceramic component 100 is not particularly limited, but assuming that the length (X direction) is L and the width (Y direction) is W, it is suitable that L/W is approximately 16 to 50. Further, it is suitable that the thickness (Z direction) is approximately 0.5 mm to 1.5 mm.

Operation of Multi-Layer Piezoelectric Ceramic Component

In the multi-layer piezoelectric ceramic component 100, a voltage can be independently applied between the first internal electrodes 102 and the second internal electrodes 103 and between the third internal electrodes 104 and the second internal electrodes 103.

When a voltage is applied between the first internal electrodes 102 and the second internal electrodes 103, an inverse piezoelectric effect occurs in the piezoelectric ceramic body 101 between the first internal electrodes 102 and the second internal electrodes 103 and causes deformation (expansion and contraction) in the X direction in the first region 101g. Further, when a voltage is applied between the third internal electrodes 104 and the second internal electrodes 103, an inverse piezoelectric effect occurs in the piezoelectric ceramic body 101 between the third internal electrodes 104 and the second internal electrodes 103 and causes deformation (expansion and contraction) in the X direction in the second region 101h.

In such a manner, in the multi-layer piezoelectric ceramic component 100, the deformation in the first region 101g and the deformation in the second region 101h can be independently controlled. The first region 101g and the second region 101h are separately deformed in the X direction, and thus the multi-layer piezoelectric ceramic component 100 can be deformed (bent) in the Z direction.

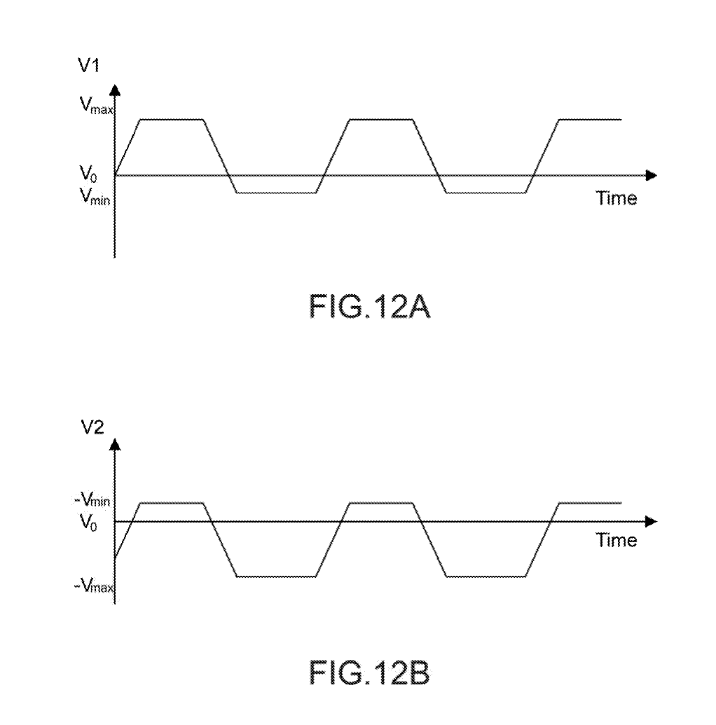

FIGS. 12A and 12B show examples of voltage waveforms applied to the multi-layer piezoelectric ceramic component 100. FIG. 12A shows a waveform of a voltage (V1) applied between the first internal electrodes 102 and the second internal electrodes 103. FIG. 12B shows a waveform of a voltage (V2) applied between the third internal electrodes 104 and the second internal electrodes 103. It should be noted that V₀ represents a potential of the second internal electrodes 103. As shown in FIGS. 12A and 12B, when the voltage V1 and the voltage V2 are set as reverse bias voltages in the same phase, one of the first region 101g and the second region 101h can be expanded, and the other one of the first region 101g and the second region 101h can be contracted.

It should be noted that when the thickness of the first region 101g and the thickness of the second region 101h have a ratio of 1:1, the first region 101g and the second region 101h are symmetrical with each other in terms of the amount of deformation, which is suitable. Further, the waveforms of the voltage V1 and the voltage V2 are not limited to those shown in FIGS. 12A and 12B and may be each a sine wave or a triangle wave.

Regarding Structure Without Side Margin

As described above, the multi-layer piezoelectric ceramic component 100 has a structure in which the first internal electrodes 102, the second internal electrodes 103, and the third internal electrodes 104 are exposed at the first side surface 101a and the second side surface 101b.

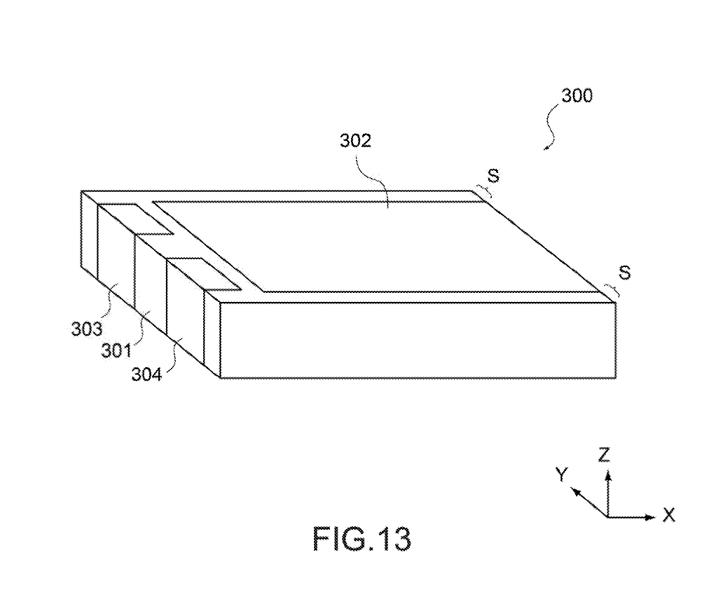

FIG. 13 is a perspective view of a multi-layer piezoelectric ceramic component 300 according to a comparative example.

As shown in FIG. 13, the multi-layer piezoelectric ceramic component 300 includes a piezoelectric ceramic body 301, a surface electrode 302, a first terminal electrode 303, and a second terminal electrode 304. Further, the multi-layer piezoelectric ceramic component 300 includes internal electrodes (not shown) corresponding to the first internal electrodes 102, the second internal electrodes 103, and the third internal electrodes 104.

In the multi-layer piezoelectric ceramic component 300, the internal electrodes are not exposed at the side surfaces and end surfaces and are embedded in the piezoelectric ceramic body 301. As shown in FIG. 13, side margins S made of a piezoelectric material are each provided on the side surface side of the internal electrodes.

The side margins S act as restraint portions that suppress the displacement of the multi-layer piezoelectric ceramic component 300 when the multi-layer piezoelectric ceramic component 300 is driven. This reduces displacement performance of the multi-layer piezoelectric ceramic component 300.

To the contrary, the multi-layer piezoelectric ceramic component 100 does not include side margins. Thus, it is possible to generate large displacement without receiving a restraint effect provided by the side margins and to prevent the displacement performance from being reduced.

Moreover, in the multi-layer piezoelectric ceramic component 100, the first internal electrodes 102 and the third internal electrodes 104 are extended from the first end surface 101c to the first side surface 101a or the second side surface 101b (see FIG. 1). This can mitigate the influence of stress, resulting in increasing the amount of displacement and improving the strength of the element.

Regarding Insulating Film

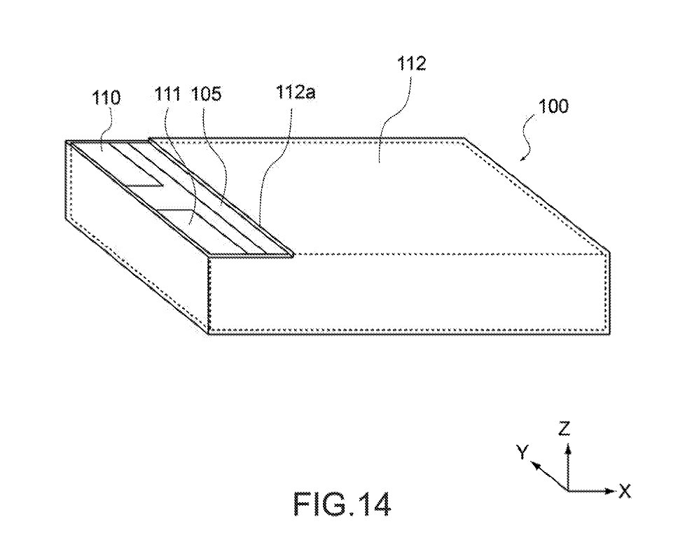

The multi-layer piezoelectric ceramic component 100 may include an insulating film. FIG. 14 is a perspective view of the multi-layer piezoelectric ceramic component 100 including an insulating film 112.

As shown in FIG. 14, the insulating film 112 covers the outer periphery of the multi-layer piezoelectric ceramic component 100. The insulating film 112 includes an opening 112a from which the first surface terminal electrode 110, the second surface terminal electrode 111, and the first surface electrode 105 are partially exposed. Electrical connection to the first surface terminal electrode 110, the second surface terminal electrode 111, and the first surface electrode 105 via the opening 112a is established.

The range covered with the insulating film 112 is not limited to the range shown in FIG. 14 and only needs to cover at least the first side surface 101a and the second side surface 101b at which the first internal electrodes 102, the second internal electrodes 103, and the third internal electrodes 104 are exposed.

The material of the insulating film 112 is not particularly limited as long as the material is an insulating material. For example, an insulating resin such as a SiN or acrylic resin is suitable. It should be noted that the insulating film 112 is made of a material different from the material of the piezoelectric ceramic body 101, and a soft material can be used therefor. Thus, a restraint effect provided by the insulating film 112 can be made significantly small.

Regarding Production Method

A production method for the multi-layer piezoelectric ceramic component 100 will be described.

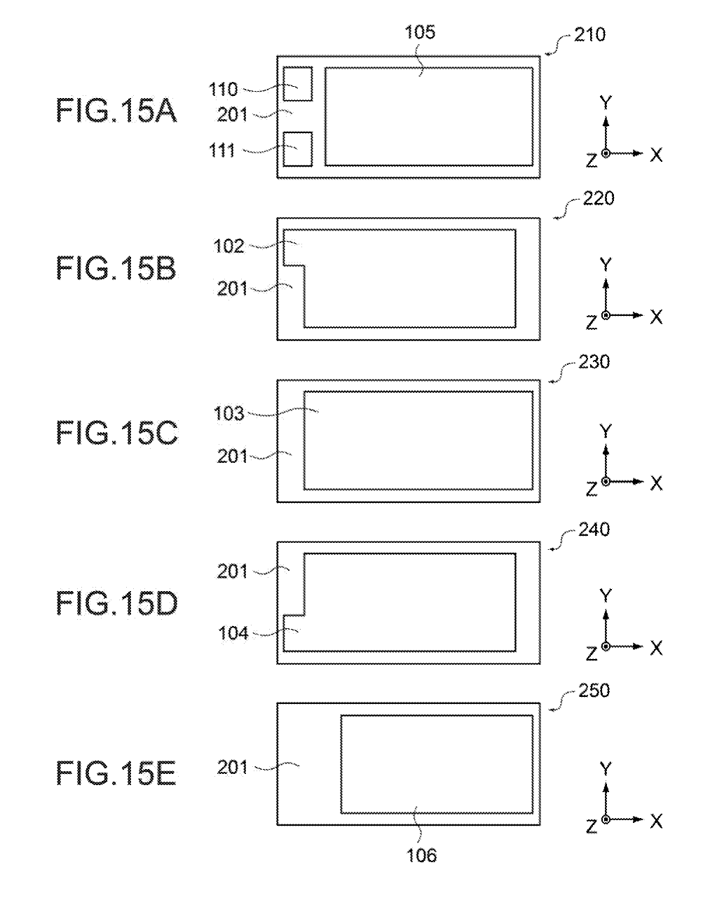

The multi-layer piezoelectric ceramic component 100 can be produced by laminating ceramic green sheets. FIGS. 15A to 15E are schematic views of respective ceramic green sheets. FIG. 15A shows a ceramic green sheet 210 including the first surface electrode 105, the first surface terminal electrode 110, the second surface terminal electrode 111, and a piezoelectric ceramic body 201. FIG. 15B shows a ceramic green sheet 220 including the first internal electrode 102 and the piezoelectric ceramic body 201.

FIG. 15C shows a ceramic green sheet 230 including the second internal electrode 103 and the piezoelectric ceramic body 201. FIG. 15D shows a ceramic green sheet 240 including the third internal electrode 104 and the piezoelectric ceramic body 201. FIG. 15E shows a ceramic green sheet 250 including the second surface electrode 106 and the piezoelectric ceramic body 201.

In each ceramic green sheet, the first surface electrode 105, the first surface terminal electrode 110, the second surface terminal electrode 111, the first internal electrodes 102, the second internal electrodes 103, the third internal electrodes 104, and the second surface electrode 106 may be each an electrically conductive pattern formed by applying an electrically conductive paste to the piezoelectric ceramic body 201. Each electrically conductive pattern is formed on the inner side of the outer edge of the ceramic green sheet. The electrically conductive paste may be a paste including the base metal.

First, the ceramic green sheet 240 and the ceramic green sheet 230 are laminated in this order on the ceramic green sheet 250. Moreover, the ceramic green sheets 240 and the ceramic green sheets 230 are alternately laminated.

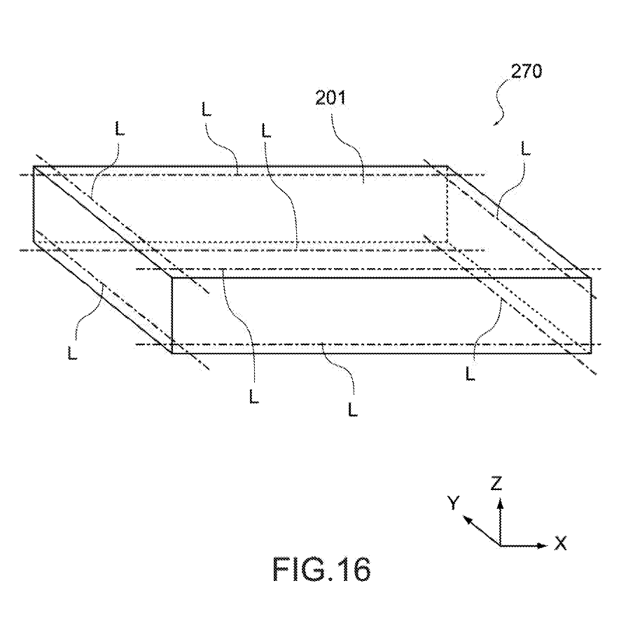

Subsequently, the ceramic green sheets 220 and the ceramic green sheets 230 are alternately laminated, and the ceramic green sheet 210 is laminated thereon. Further, a ceramic green sheet including only a piezoelectric ceramic body is laminated thereon. Subsequently, this laminate is pressure-bonded, and a binder is removed by heating or the like. FIG. 16 is a schematic view of a laminate 270 thus formed.

The first internal electrodes 102, the second internal electrodes 103, the third internal electrodes 104, the first surface electrode 105, the second surface electrode 106, the first surface terminal electrode 110, and the second surface terminal electrode 111 are disposed in the piezoelectric ceramic body 201 and are not exposed at a surface of the laminate 270.

Subsequently, sintering is performed. As described above, each electrode is not exposed at the surface of the laminate 270 and thus not oxidized by sintering. Accordingly, if the base metal is used as a material of each electrode, it is unnecessary to strictly control the partial pressure of oxygen during sintering on the basis of the Ellingham diagram, and it is possible to perform sintering in an atmosphere in which the partial pressure of oxygen is high.

Specifically, assuming that the partial pressure of oxygen, which is to be an index of oxidation in the Ellingham diagram, for a base metal to be used is A [atm], sintering can be performed at the partial pressure of oxygen in the range from A up to A*10² [atm]. When the laminate 270 is sintered at a partial pressure of oxygen that is higher than the partial pressure of oxygen of A*10² [atm], a structural defect is induced by a differential shrinkage derived from a difference in thermal expansion coefficient between the ceramic layers and the internal electrodes. This makes it difficult to sinter the laminate 270 due to a problem different from a boundary of an oxidation-reduction reaction raised on the Ellingham diagram.

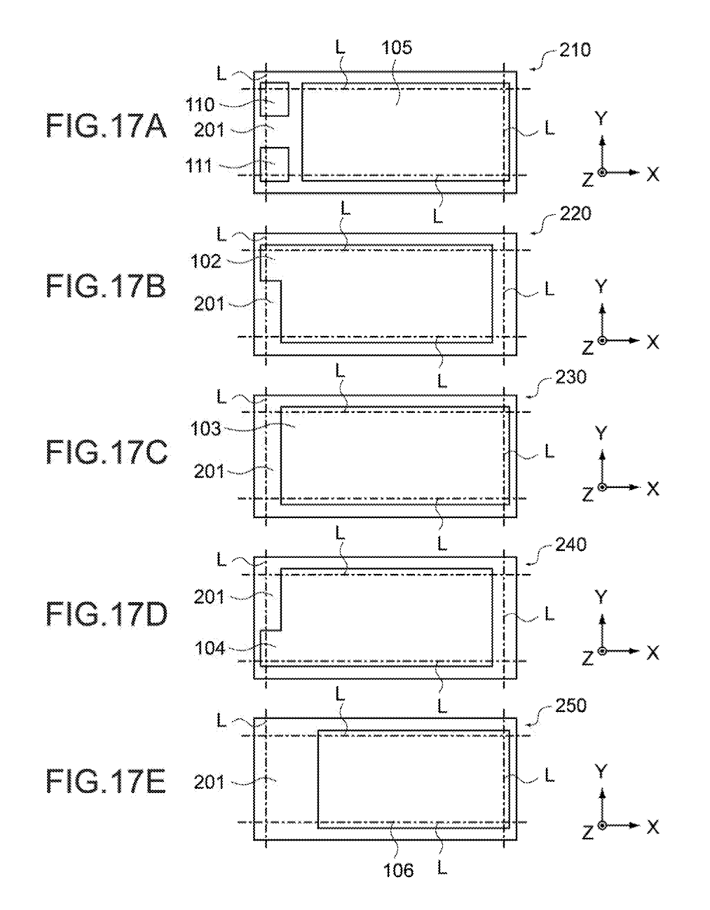

After sintering, the laminate 270 is cut. FIG. 16 shows cut positions in the laminate 270 by lines L. Further, FIGS. 17A to 17E each show cut positions in the respective ceramic green sheets by the lines L. As shown in FIGS. 17A to 17E, the laminate 270 is cut such that the first internal electrodes 102, the second internal electrodes 103, and the third internal electrodes 104 are exposed at the first side surface 101a and the second side surface 101b, the first internal electrodes 102 and the third internal electrodes 104 are exposed at the first end surface 101c, and the second internal electrodes 103 are exposed at the second end surface 101d (see FIGS. 1 and 2). The cutting of the laminate 270 can be performed by dicing or laser irradiation.

It should be noted that the positions indicated by the lines L may be provided with markers in advance. The markers become the reference for cutting. The markers can be provided by back-calculating a cutting pitch from a shrinking percentage associated with the sintering of the piezoelectric ceramic body 201. The above-mentioned lines L are imaginary lines connecting the markers, and the imaginary lines can be formed to pass through the respective electrically conductive patterns as described above. If the second internal electrodes 103 are exposed when the first end surface 101c side is cut, an open circuit failure occurs. However, if the markers are provided attentively, the second internal electrodes 103 can be prevented from being exposed.

Subsequently, by heat treatment, the first end surface terminal electrode 107 and the third end surface terminal electrode 109 are formed on the first end surface 101c, and the second end surface terminal electrode 108 is formed on the second end surface 101d.

Subsequently, the insulating film 112 including the opening 112a is formed (see FIG. 14). The insulating film 112 can be formed by a method such as mist deposition, sputtering, or dipping.

Subsequently, the first surface terminal electrode 110 and the second surface terminal electrode 111 are electrically connected, and a DC voltage is applied. This causes a polarizing process and activates the piezoelectric ceramic body 101.

The multi-layer piezoelectric ceramic component 100 can be produced as described above. It should be noted that the production method for the multi-layer piezoelectric ceramic component 100 is not limited to the method described herein.

Regarding Cut Surface

As described above, in the production process of the multi-layer piezoelectric ceramic component 100, the laminate 270 is cut after sintering. This cutting can improve the control of the dimension in the longitudinal direction (X direction) and maximize an active portion by the removal of the restraint portions (side margins).

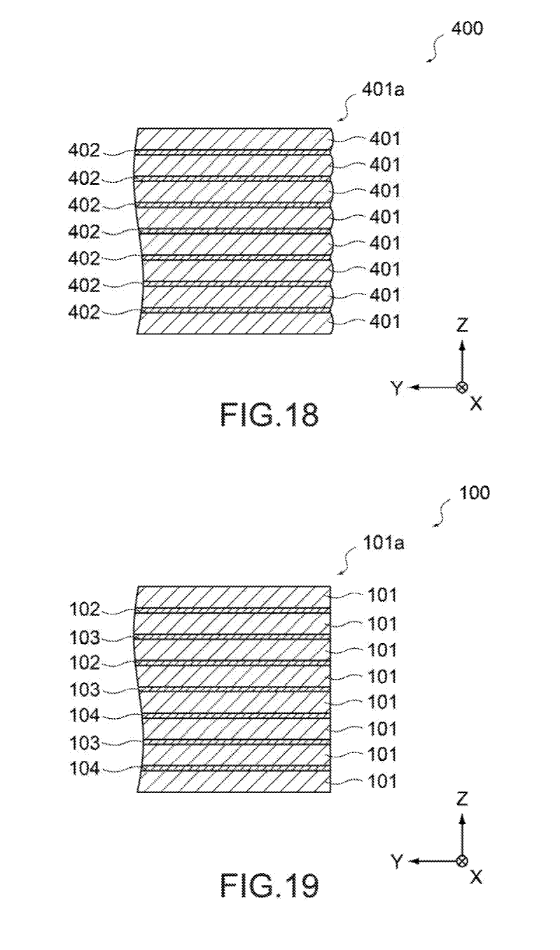

FIG. 18 is a cross-sectional view of a side surface 401a of a multi-layer piezoelectric ceramic component 400 according to a comparative example. The multi-layer piezoelectric ceramic component 400 is formed by sintering after the laminate is cut in the production process. FIG. 19 is a cross-sectional view of the first side surface 101a of the multi-layer piezoelectric ceramic component 100.

As shown in FIG. 18, in the multi-layer piezoelectric ceramic component 400, the side surface 401a has macro undulations by a differential shrinkage between internal electrodes 402 and piezoelectric ceramic bodies 401. This makes it easy to cause peel-off of an insulating film formed on the side surface 401a.

To the contrary, in the multi-layer piezoelectric ceramic component 100 as shown in FIG. 19, the first side surface 101a is flat and thus has improved surface accuracy and straightness, which makes it possible to uniformly form the insulating film 112 (see FIG. 14) and improve adhesion properties thereof. This can improve performance in displacement and generative force while suppressing the peel-off the insulating film 112 when the multi-layer piezoelectric ceramic component 100 is driven. The same holds true for the surfaces other than the first side surface 101a.

Regarding Piezoelectric Device

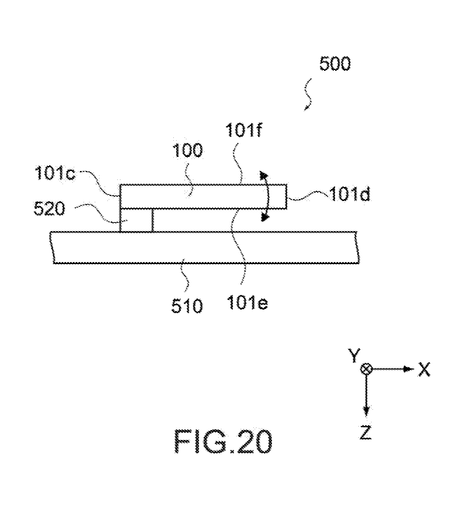

The multi-layer piezoelectric ceramic component 100 can be mounted to a vibration member to configure a piezoelectric device. FIG. 20 is a schematic view of a piezoelectric device 500 including the multi-layer piezoelectric ceramic component 100. As shown in FIG. 20, the piezoelectric device 500 includes the multi-layer piezoelectric ceramic component 100, a vibration member 510, and a joint 520.

The vibration member 510 is a metal plate or a glass panel of a display and is not particularly limited. The joint 520 is made of a resin or the like and joins the multi-layer piezoelectric ceramic component 100 to the vibration member 510.

In the multi-layer piezoelectric ceramic component 100, a region of the upper surface 101e on the first end surface 101c side is joined to the joint 520. Wiring (not shown) is connected to the first surface terminal electrode 110, the second surface terminal electrode 111, and the first surface electrode 105 via the joint 520.

When a voltage is applied to each electrode, as described above, the multi-layer piezoelectric ceramic component 100 is deformed in the Z direction (arrow in FIG. 20). This allows the vibration member 510 to vibrate. It should be noted that the method of mounting the multi-layer piezoelectric ceramic component 100 is not limited to that described herein. For example, the entire upper surface 101e may be joined to the joint 520.

### Modified Example

In the above description, the first internal electrodes 102 and the third internal electrodes 104 are exposed at the first side surface 101a, the second side surface 101b, and the first end surface 101c, and the second internal electrodes 103 are exposed at the first side surface 101a, the second side surface 101b, and the second end surface 101d, but the multi-layer piezoelectric ceramic component 100 is not limited thereto. At least one of the first internal electrode 102, the second internal electrode 103, or the third internal electrode 104 may be exposed at any of the surfaces of the piezoelectric ceramic body 101.

Further, in the above description, the multi-layer piezoelectric ceramic component 100 is a bimorph multi-layer piezoelectric actuator in which a piezoelectric element is formed between the first internal electrodes 102 and the second internal electrodes 103 and a piezoelectric element is formed between the third internal electrodes 104 and the second internal electrodes 103, but the multi-layer piezoelectric ceramic component 100 is not limited thereto. The multi-layer piezoelectric ceramic component 100 may include only the first internal electrodes 102 and the second internal electrodes 103 without including the third internal electrodes 104.

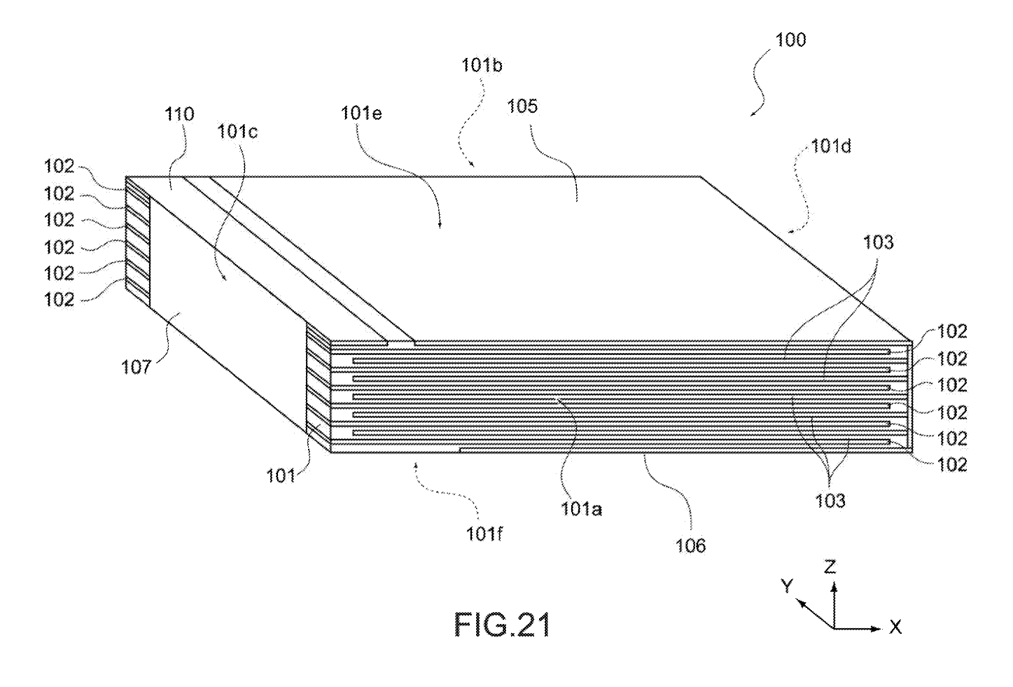

FIG. 21 is a perspective view of a multi-layer piezoelectric ceramic component 100 including no third internal electrodes 104. As shown in FIG. 21, the first internal electrodes 102 are connected to the first end surface terminal electrode 107 on the first end surface 101c. At least one of the first internal electrode 102 or the second internal electrode 103 can include a base metal.

What is claimed is:

1. A method of producing a multi-layer piezoelectric ceramic component, the method comprising:
laminating ceramic green sheets to form a laminate, each of the ceramic green sheets being made of a piezoelectric ceramic material and including an electrically conductive pattern, the electrically conductive pattern including a base metal, being to be an internal electrode, and being formed on an inner side of an outer edge of the ceramic green sheet;
sintering the laminate; and
cutting the sintered laminate and causing the internal electrodes to be exposed.

2. The method of producing a multi-layer piezoelectric ceramic component according to claim 1, wherein
the electrically conductive pattern includes an electrically conductive paste including Ni, Cu, or a Ni alloy.

3. The method of producing a multi-layer piezoelectric ceramic component according to claim 1, wherein
the laminate includes markers, and
the causing the internal electrodes to be exposed includes cutting the laminate at positions of the markers.

4. The method of producing a multi-layer piezoelectric ceramic component according to claim 3, wherein
the markers are formed such that an imaginary line connecting the markers passes through the electrically conductive pattern.

5. The method of producing a multi-layer piezoelectric ceramic component according to claim 1, wherein
the internal electrodes include first internal electrodes and second internal electrodes, the second internal electrodes being laminated alternately with the first internal electrodes at predetermined distances from the respective first internal electrodes in a thickness direction.

6. The method of producing a multi-layer piezoelectric ceramic component according to claim 5, wherein
the laminate is cut to form a piezoelectric ceramic body, the piezoelectric ceramic body
having a cuboid shape in which a length is larger than a width and the width is larger than a thickness, and
having an upper surface and a lower surface facing each other in the thickness direction, a first end surface and a second end surface facing each other in a length direction, and a pair of side surfaces facing each other in a width direction,
the first internal electrodes are drawn to the first end surface, and
the second internal electrodes are drawn to the second end surface.

7. The method of producing a multi-layer piezoelectric ceramic component according to claim 6, wherein
the first internal electrodes and the second internal electrodes each have a width equal to a distance between the pair of side surfaces.

8. The method of producing a multi-layer piezoelectric ceramic component according to claim 5, wherein
the internal electrodes further include third internal electrodes that are laminated alternately with the second internal electrodes at predetermined distances from the respective second internal electrodes in the thickness direction.

9. The method of producing a multi-layer piezoelectric ceramic component according to claim 8, wherein
the laminate is cut to form a piezoelectric ceramic body, the piezoelectric ceramic body
having a cuboid shape in which a length is larger than a width and the width is larger than a thickness, and
having an upper surface and a lower surface facing each other in the thickness direction, a first end surface and a second end surface facing each other in a length direction, and a pair of side surfaces facing each other in a width direction,
the first internal electrodes are drawn to the first end surface,
the second internal electrodes are drawn to the second end surface, and
the third internal electrodes are drawn to the first end surface.

10. The method of producing a multi-layer piezoelectric ceramic component according to claim 9, wherein
the first internal electrodes, the second internal electrodes, and the third internal electrodes each have a width equal to a distance between the pair of side surfaces.

11. A multi-layer piezoelectric ceramic component, comprising:
a piezoelectric ceramic body; and
internal electrodes each including a base metal, being formed in the piezoelectric ceramic body, and being exposed at a surface of the piezoelectric ceramic body.

12. A piezoelectric device, comprising:
a vibration member; and
a multi-layer piezoelectric ceramic component mounted to the vibration member,
the multi-layer piezoelectric ceramic component including
a piezoelectric ceramic body, and
internal electrodes each including a base metal, being formed in the piezoelectric ceramic body, and being exposed at a surface of the piezoelectric ceramic body.
